(19) United States
(12) Patent Application Publication
(10) Pub. No.: US 2026/0144041 A1
(43) Pub. Date: May 21, 2026

(54) METAL LEVEL OF AN INTERCONNECTION STRUCTURE

(71) Applicant: STMicroelectronics International N.V., Geneva (CH)

(72) Inventors: Jean-Christophe GIRAUDIN, Saint-Nazaire-Les-Eymes (FR); Daniel BENOIT, Grenoble (FR); Rossella RANICA, Crolles (FR)

(73) Assignee: STMicroelectronics International N.V., Geneva (CH)

(21) Appl. No.: 19/344,229

(22) Filed: Sep. 29, 2025

(30) Foreign Application Priority Data
Oct. 3, 2024 (FR) FR2410648

(51) Int. Cl. H01L 23/522; H01L 21/768; H01L 23/528; H01L 23/532

(52) U.S. Cl. CPC H10W 20/42; H10W 20/057; H10W 20/062; H10W 20/088; H10W 20/092; H10W 20/097; H10W 20/435; H10W 20/47

(57) ABSTRACT

The present description concerns a manufacturing method. A first dielectric layer, a first oxide layer, a second dielectric layer, and a second oxide layer are successively deposited on a first metal level. An anneal is performed before depositing a third dielectric layer. A via and a line metallization of a second metal level are then formed through the dielectric and oxide layers, all the way to the first metal level.

### CROSS-REFERENCE TO RELATED APPLICATION(S)

This application claims the priority benefit of French patent application number 2410648, filed on Oct. 3, 2024, entitled “Metal level of an interconnection structure,” which is hereby incorporated by reference to the maximum extent allowable by law.

### BACKGROUND

### Technical Field

The present disclosure generally concerns integrated electronic circuits, and, more particularly the interconnection structures of these electronic circuits.

### Description of the Related Art

Known integrated electronic circuits comprise a semiconductor layer having electronic components such as transistors formed inside and on top of it, and an interconnection structure resting on the semiconductor layer.

Generally, an interconnection structure comprises portions of conductive lines, also known as line metallizations, and vias coupling line metallizations together, to electronic components of the integrated circuit, and to contact pads arranged on the side of the interconnection structure opposite to the semiconductor layer. The vias and line metallizations are embedded in insulating layers of the interconnection structure. The interconnection structure is organized in metal levels stacked one on top of the other. Each metal level comprises line metallizations and vias electrically connecting the line metallizations of the metal level to conductive elements arranged below this metal level, for example to line metallizations of an underlying metal level of the interconnection structure.

Known interconnection structures and their manufacturing methods have disadvantages. More particularly, the metal levels of known interconnection structures and the known methods of manufacturing these metal levels have disadvantages.

### BRIEF SUMMARY

There exists a use for overcoming all or part of the disadvantages of known methods of manufacturing a metal level of an interconnection structure. For example, there exists a use for overcoming all or part of the disadvantages of known methods of manufacturing an interconnection structure.

There also exists a use for overcoming all or part of the disadvantages of a metal level of known interconnection structures. For example, there exists a use for overcoming all or part of the disadvantages of known interconnection structures.

An embodiment overcomes all or part of the disadvantages of known methods of manufacturing a metal level of an interconnection structure.

For example, an embodiment overcomes all or part of the disadvantages of known methods of manufacturing an interconnection structure.

An embodiment overcomes all or part of the disadvantages of a metal level of known interconnection structures.

For example, an embodiment overcomes all or part of the disadvantages of known interconnection structures.

An embodiment provides a manufacturing method comprising the following steps. Depositing a first dielectric layer on top of and in contact with a first metal level of an interconnection structure. Depositing a first oxide layer on top of and in contact with the first dielectric layer. Depositing a second dielectric layer on the first oxide layer. Depositing a second oxide layer on top of and in contact with the second dielectric layer, performing a first anneal, and depositing a third dielectric layer on top of and in contact with the second oxide layer. Etching a first cavity down to a conductive element of the first metal level, the first cavity running through at least the first oxide layer and the first dielectric layer. Etching a second cavity through the third dielectric layer, the second oxide layer, and the second dielectric layer, so that the first cavity emerges onto the bottom of the second cavity. Filling the first cavity with at least one conductive material to form therein a conductive via of a second metal level of the interconnection structure. Filling the second cavity with at least one conductive material to form therein a line metallization of the second metal level of the interconnection structure. Performing a first chemical-mechanical polishing down to the third dielectric layer, after the filling of the second cavity.

According to an embodiment, the first and second oxide layers are made of silicon oxide, preferably of undoped silicon oxide.

According to an embodiment, the first oxide layer is made of a material selectively etchable over the material of the first dielectric layer.

According to an embodiment, the first dielectric layer is made of silicon nitride.

According to an embodiment, the second oxide layer is made of a material selectively etchable over the material of the second dielectric layer.

According to an embodiment, the second dielectric layer is made of aluminum oxide or of silicon nitride.

According to an embodiment, the third dielectric layer is made of aluminum oxide or of silicon nitride.

According to an embodiment:
the second dielectric layer is deposited on top of and in contact with the first oxide layer;
the etching of the first cavity is carried out after the deposition of the third dielectric layer;
the first cavity is further etched through the third dielectric layer, the second oxide layer, and the second dielectric layer; and
the first and second cavities are filled simultaneously, said at least one conductive material filling the first cavity and said at least one conductive material filling the second cavity being identical.

According to an embodiment, the deposition of the first oxide layer is followed by a second anneal, and the second anneal is followed by the deposition of a fourth dielectric layer on top of and in contact with the first oxide layer.

According to an embodiment:
the etching and the filling of the first cavity are carried out after the deposition of the fourth dielectric layer and before the deposition of the second dielectric layer, the first cavity being etched through the fourth dielectric layer, the first oxide layer, and the first dielectric layer;
a second chemical-mechanical polishing down to the fourth dielectric layer is carried out after the filling of the first cavity and before the deposition of the second dielectric layer;
the second dielectric layer is deposited on top of and in contact with the fourth dielectric layer and a top of the conductive via of the second metal level of the interconnection structure.

According to an embodiment, the etching of the second cavity is stopped on the top of the conductive via and the fourth dielectric layer, the first cavity filled by said conductive via emerging onto the bottom of the second cavity.

According to an embodiment, the fourth dielectric layer is made of aluminum oxide or of silicon nitride.

Another embodiment provides a device comprising an interconnection structure, the interconnection structure comprising a first metal level and a second metal level resting on the first metal level, the second metal level comprising:
a first dielectric layer resting on top of and in contact with the first metal level;
a first oxide layer resting on top of and in contact with the first dielectric layer;
a second dielectric layer arranged over the first oxide layer;
a second oxide layer resting on top of and in contact with the second dielectric layer; and
a third dielectric layer resting on top of and in contact with the second oxide layer;
a line metallization extending through the third dielectric layer, the second oxide layer, and the second dielectric layer, the line metallization being flush with an upper surface of the third dielectric layer;
a conductive via extending into the first oxide layer and through the first dielectric layer, from the line metallization to a conductive element of the first metal level.

According to an embodiment, in the second metal level, the line metallization is bordered by the third dielectric layer along its entire upper periphery.

According to an embodiment:
the second dielectric layer lies on top of and in contact with the first oxide layer, the line metallization being able to partially extend into the first oxide layer; or
a fourth dielectric layer lies on top of and in contact with the first oxide layer, the second dielectric layer lies on top of and in contact with the fourth dielectric layer, the conductive via being flush with an upper surface of the fourth dielectric layer and being bordered by the fourth dielectric layer along its entire upper periphery.

### BRIEF DESCRIPTION OF THE SEVERAL VIEWS OF THE DRAWINGS

The foregoing features and advantages, as well as others, will be described in detail in the rest of the disclosure of specific embodiments given as an illustration and not limitation with reference to the accompanying drawings, in which:

FIG. 1 shows, in a simplified cross-section view, an example of an integrated circuit;

FIG. 2 shows, in a simplified cross-section view, an embodiment of a step of a manufacturing method;

FIG. 3 shows, in a simplified cross-section view, an embodiment of a step of a manufacturing method following the step of FIG. 2;

FIG. 4 shows, in a simplified cross-section view, an embodiment of a step of a manufacturing method following the step of FIG. 3;

FIG. 5 shows, in a simplified cross-section view, an embodiment of a step of a manufacturing method following the step of FIG. 4;

FIG. 6, in a simplified cross-section view, an embodiment of a step of a manufacturing method following the step of FIG. 5;

FIG. 7 shows, in a simplified cross-section view, an embodiment of a step of a manufacturing method following the step of FIG. 6;

FIG. 8 shows, in a simplified cross-section view, another embodiment of a step of a manufacturing method following the step of FIG. 2;

FIG. 9 shows, in a simplified cross-section view, an embodiment of a step of a manufacturing method following the step of FIG. 8;

FIG. 10 shows, in a simplified cross-section view, an embodiment of a step of a manufacturing method following the step of FIG. 9;

FIG. 11 shows, in a simplified cross-section view, an embodiment of a step of a manufacturing method following the step of FIG. 10; and

FIG. 12 shows, in a simplified cross-section view, an embodiment of a step of a manufacturing method following the step of FIG. 11.

### DETAILED DESCRIPTION

Like features have been designated by like references in the various figures. In particular, the structural and/or functional features that are common among the various embodiments may have the same references and may dispose identical structural, dimensional and material properties.

For clarity, only those steps and elements which are useful to the understanding of the described embodiments have been shown and are described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, where reference is made to absolute position qualifiers, such as “front,” “back,” “top,” “bottom,” “left,” “right,” etc., or relative position qualifiers, such as “top,” “bottom,” “upper,” “lower,” etc., or orientation qualifiers, such as “horizontal,” “vertical,” etc., reference is made unless otherwise specified to the orientation of the drawings.

Unless specified otherwise, the expressions “about,” “approximately,” “substantially,” and “in the order of” signify plus or minus 10% or 10°, preferably of plus or minus 5% or 5°.

In the present application, unless specified otherwise, the terms “first,” “second,” “third,” etc., are used to distinguish layers, elements, or steps from one another, without there being any relationship of order between these layers, elements, or steps.

In the present disclosure, unless specified otherwise, the expressions “a first element deposited on a second element” and “a first element resting on a second element” mean that the first element is deposited or rests on the second element, with or without the interposition of a third element between the first and second elements.

FIG. 1 shows, in a simplified cross-section view, an example of an integrated circuit 1 comprising an interconnection structure 100 resting on a semiconductor layer 102 of circuit 1.

Although this is not illustrated in FIG. 1, electronic components such as transistors are formed, or arranged, inside and on top of layer 102.

Interconnection structure 100 comprises metal levels stacked one on top of the other. In the example of FIG. 1, interconnection structure 100 comprises six successive metal levels L1, L2, L3, L4, L5, and L6, metal level L1 being the closest to layer 102, and metal level L6 being the most distant from layer 102. However, in other examples not shown, the number of metal levels may be different from six, for example be equal to any number greater than or equal to two, preferably three.

Each metal level L1, L2, L3, L4, L5, L6 of the interconnection structure comprises line metallizations 104 and conductive vias 106, or via metallizations 106. In order not to overload FIG. 1, only one line metallization of metal level L2 and one via metallization 106 of level L2 are referenced in FIG. 1. For example, metallizations 104 extend lengthwise in directions parallel to an upper surface of layer 102, vias 106 extending lengthwise in directions orthogonal to this upper surface of layer 102.

In each of the metal levels other than level L1, each via 106 electrically connects a line metallization 104 of the metal level to a line metallization 104 of the underlying metal level, that is, of the metal level having the metal level comprising this via 106 resting on top of it and in contact therewith. For example, the via 106 referenced in FIG. 1, which belongs to metal level L2, electrically connects a line metallization 104 of metal level L2 to a line metallization 104 of metal level L1 having metal level L2 resting on top of it and in contact therewith.

In metal level L1, each via 106 electrically connects a line metallization 104 of metal level L1 to a component formed inside and on top of layer 102.

Although this is not shown in FIG. 1, the interconnection structure may comprise, in addition to conductive vias 106, conductive vias (not shown) which connect line metallizations 104 to components formed in structure 100, for example to electrodes of a capacitive element or of an inductance formed in structure 100.

In interconnection structure 100, line metallizations 104 and via metallizations 106 are embedded in insulating layers. For example, these insulating layers comprise oxide layers, such as silicon oxide layers. For example, each metal level of structure 100 comprises a layer of oxide, for example of silicon oxide, preferably of undoped silicon oxide, crossed by the via metallizations 106 of this level, and a layer of oxide, for example of silicon oxide, preferably of undoped silicon oxide, crossed by the line metallizations 104 of this level.

On the side of its surface opposite to layer 102, that is, on its upper surface side in FIG. 1, interconnection structure 100 may comprise contact pads 108 electrically coupled to the metal level L6 most distant from layer 102. For example, each pad 108 is in contact with a corresponding line metallization 104 of level L6.

Usually, to manufacture interconnection structure 100, the metal levels are formed one after the other. Further, each metal level is formed by steps of deposition of insulating layers, of etching of the insulating layers, and of deposition of conductive materials in the cavities obtained by etching, for example by methods commonly referred to as single damascene or double damascene.

A problem that arises in at least some of the metal levels of known interconnection structures, for example in metal levels other than that which is closest to the semiconductor layer having the interconnection structure resting thereon, or even in all metal levels, is that the oxide used to form at least some of the insulating layers of a metal level may be of poor quality, for example due to traces of moisture in the oxide.

To overcome this disadvantage, it may be provided to increase the temperature during the deposition of the oxide, for example to carry out the oxide depositions at temperatures higher than or equal to 350° C. A final anneal may also be provided after the forming of the last metal level of the interconnection structure, this final anneal being carried out at a temperature higher than the oxide deposition temperatures, for example at a temperature higher than or equal to 400° C. This improves the quality of the oxide formed.

However, improving the quality of the deposited oxide by increasing the high deposition or anneal temperatures, for example, above 350° C., may cause damage to electronic components of the circuit which are formed prior to the interconnection structure, which is not desirable.

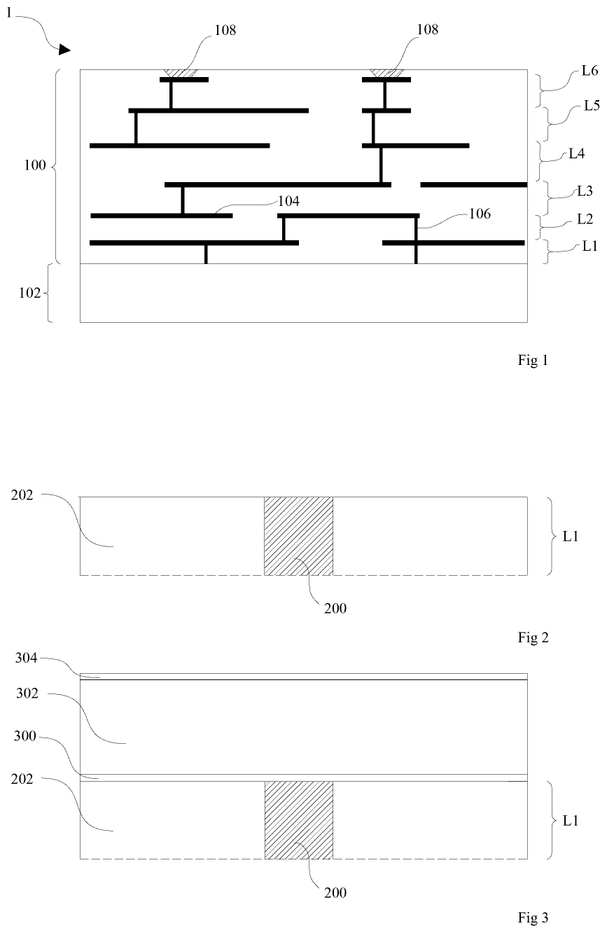

FIG. 2 shows, in a simplified cross-section view, an embodiment of a step of a method of manufacturing a metal level of an interconnection structure of the type described in relation with FIG. 1, for example the metal level L2 resting on top of and in contact with the metal level L1 closest to layer 102.

More particularly, FIG. 2 shows an upper portion of metal level L1, after the manufacturing of this metal level L1 but before the manufacturing of the next metal level L2.

Metal level L1 comprises a conductive element 200, for example a line metallization 104 of level L1, embedded in an insulating layer 202. Element 200 is flush with an upper surface of metal level L1, that is, the upper surface of layer 202. Layer 202 corresponds, for example, to a stack of a plurality of insulating layers.

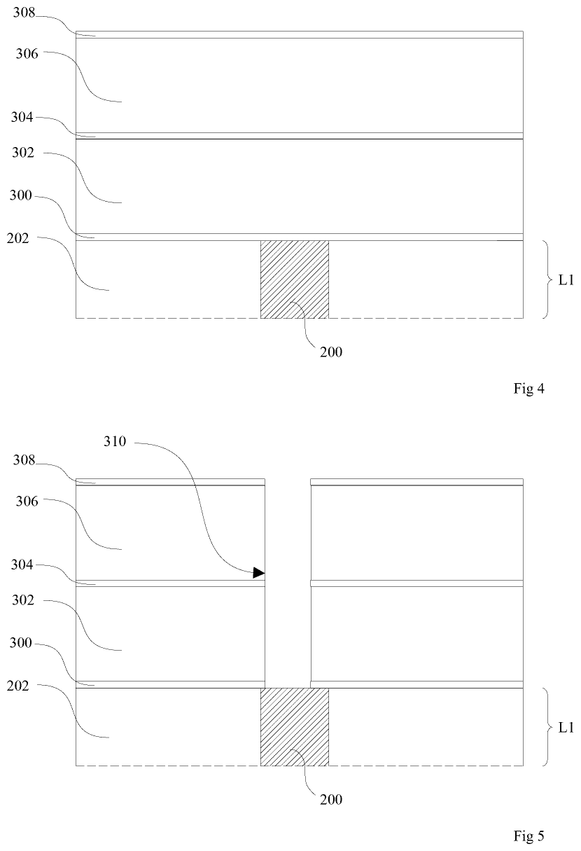

FIG. 3 shows, in a simplified cross-section view, an embodiment of a step of a manufacturing method following the step of FIG. 2.

In FIG. 3, a dielectric layer 300 has been deposited, for example by full-plate deposition, on the structure shown in FIG. 2. More specifically, layer 300 has been deposited on top of and in contact with metal level L1, or, in other words, on top of and in contact with the upper surface of metal level L1.

As an example, layer 300 comprises a single dielectric layer, for example made of silicon nitride.

As an alternative example, layer 300 corresponds to a stack of a plurality of dielectric layers, for example made of silicon nitride.

After the deposition of layer 300, an oxide layer 302 was deposited, for example by deposition over the entire wafer, on top of and in contact with layer 300.

Layer 302, for example, is referred to as an inter-metal dielectric (IMD) layer and separates the line metallizations of the metal level to which it belongs from the line metallizations of the underlying metal level.

As an example, the deposition of layer 302 is performed at a temperature lower than or equal to 300° C.

Layer 302 is, for example, made of silicon oxide, preferably of undoped silicon oxide, also referred to, for example, as undoped silicon glass (USG).

Layer 302 is thicker than layer 300, for example at least ten times as thick as layer 300. As an example, layer 302 comprises a single dielectric layer, for example made of silicon oxide. As an alternative example, layer 302 corresponds to a stack of a plurality of dielectric layers, for example made of silicon oxide.

Preferably, the material of layer 302 is selectively etchable over the material of layer 300, so that layer 300 is used as an etch stop layer during the etching of cavities in layer 302.

After the deposition of layer 302, a dielectric layer 304 has been deposited, for example by deposition, on top of (or above) layer 302. In this embodiment, layer 304 is preferably deposited on top of and in contact with layer 302. Further, the deposition of layer 304 on and in contact with the oxide layer 302 is done without prior heating treatment of the oxide layer 302.

As an example, layer 304 comprises a single dielectric layer, for example made of silicon nitride.

As an alternative example, layer 304 corresponds to a stack of a plurality of dielectric layers, for example made of silicon nitride.

As an example, layer 304 has a thickness of the same order of magnitude as the thickness of layer 300, that is, for example, the ratio of the thicknesses of layers 300 and 304 is smaller than ten, preferably smaller than 5.

FIG. 4 shows, in a simplified cross-section view, an embodiment of a step of a manufacturing method following the step of FIG. 3.

In FIG. 4, an oxide layer 306 has been deposited, for example by a deposition over the entire wafer, on the structure shown in FIG. 3. More particularly, layer 306 has been deposited on top of and in contact with layer 304.

Layer 306 is, for example, referred to as an inter-level dielectric (ILD) layer, and corresponds to an insulating layer in which the line metallizations of the metal level to which it belongs are formed.

As an example, the deposition of layer 306 is carried out at a temperature lower than or equal to 300° C.

Layer 306 is, for example, made of silicon oxide, preferably of undoped silicon oxide, also referred to, for example, as undoped silicon glass (USG).

Layer 306 is thicker than layer 304, for example at least ten times as thick as layer 304. As an example, layer 306 comprises a single dielectric layer, for example made of silicon oxide. As an alternative example, layer 306 comprises a stack of a plurality of dielectric layers, for example made of silicon oxide.

Preferably, the material of layer 306 is selectively etchable over the material of layer 304, so that layer 304 is used as an etch stop layer during the etching of cavities in layer 306.

After the deposition of layer 306, an anneal is carried out. More particularly, the anneal is carried out immediately after the deposition of layer 306, that is, for example, before any further deposition or etching step.

As an example, the anneal is carried out under a neutral nitrogen (N2) or hydrogenated nitrogen (N2H2) atmosphere.

As an example, the anneal is carried out at a temperature higher than the temperature of deposition of layers 302 and 306, but below, for example, 350° C.

As an example, the anneal is carried out at the atmospheric pressure.

As an example, the anneal is carried out without UV (Ultra Violet) treatment.

This anneal improves the quality of the oxide of layers 302 and 306, for example by removing traces of moisture in these layers.

For example, this annealing step is configured to remove, in layers 302 and 306, traces of moisture, hydrogen, and O—H bonds. In particular, the objective of this annealing step is not to remove the carbon bonds. Indeed, the objective of this annealing is not to modify the electrical properties, for example to improve the dielectric permittivity, but rather to eliminate the traces of moisture which could be absorbed by layers 302 and 306 after their depositions.

For example, in comparison, the objective of the heat treatments disclosed in US 2011/0049719 A1 is to remove porogen in low k layers when the heat treatments are calcination carried out with UV irradiation at a temperature comprised between 350 and 420° C., or burn the carbon elements in low k layer when the heat treatment is calcination carried out at 300 to 420° C. under inert gas atmosphere without UV irradiation.

These calcinating steps allow for reducing the permittivity below 3.0, and to improve the reliability, for example regarding TDDB (Time Dependent Dielectric Breakdown) tests. Thus, these calcinating steps modify the electrical properties of the low k layers.

After the anneal, a dielectric layer 308 is deposited, for example by full-plate deposition, on top of and in contact with layer 306. The deposition of the layer is performed immediately after the anneal, that is, before any further deposition or etching step.

As an example, layer 308 enables to protect the oxide of layer 306 after the anneal, to preserve the qualities of the oxide, layer 308 being referred to, for example, as an encapsulation layer.

As an example, layer 308 comprises a single dielectric layer, for example made of silicon nitride or of aluminum oxide.

As an alternative example, layer 308 corresponds to a stack of a plurality of dielectric layers, for example made of silicon nitride and/or of aluminum oxide.

As an example, layer 308 has a thickness of the same order of magnitude as the thicknesses of layers 300 and 304, that is, for example, the ratio of the thicknesses of layers 300 (or 304) and 308 is smaller than ten, preferably smaller than 5.

FIG. 5 shows, in a simplified cross-section view, an embodiment of a step of a manufacturing method following the step of FIG. 4.

In FIG. 5, a cavity 310 has been etched down to the conductive element 200 of metal level L1. The etching of cavity 310 is preferably stopped on the upper surface of conductive element 200. Cavity 310 runs through at least layer 300 and layer 302.

More particularly, in this embodiment where cavity 310 is etched after the deposition of layer 308, cavity 310 runs through all layers 308, 306, 304, 302, and 300.

As an example, the etching of cavity 310 is stopped on layer 300, which is then used as an etch stop layer, after which the portion of layer 300 exposed at the bottom of cavity 310 is removed by etching, so that cavity 310 extends all the way to element 200.

As an example, element 200 is flush with the bottom of cavity 310.

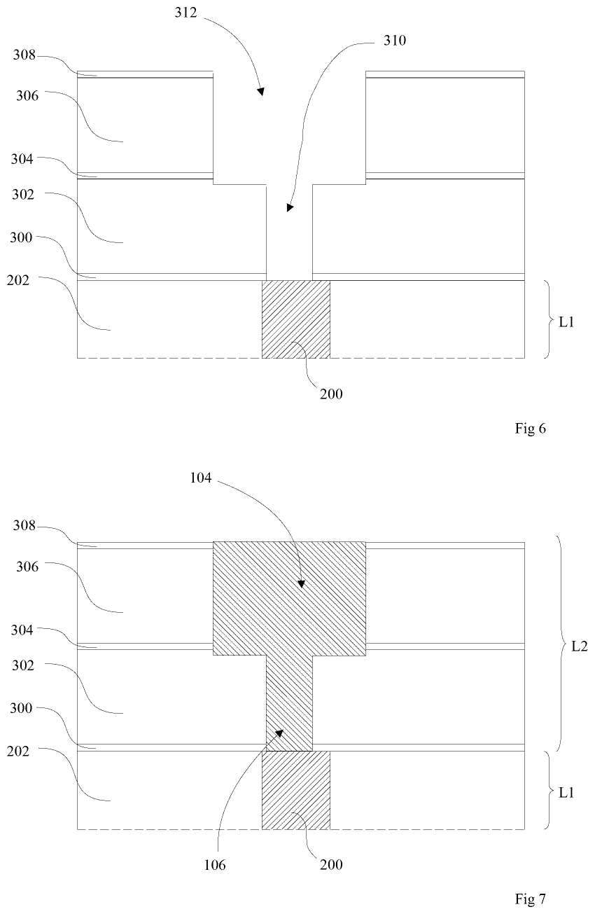

FIG. 6 shows, in a simplified cross-section view, an embodiment of a step of a manufacturing method following the step of FIG. 5.

In FIG. 6, a cavity 312 has been etched through layers 308, 306, and 304. Cavity 312 may, as shown in FIG. 6, only partially penetrate into layer 302.

Cavity 312 is etched so that cavity 310 emerges onto the bottom of cavity 312.

As an example, the etching of cavity 312 is stopped on layer 304, which is then used as an etch stop layer, after which the portion of layer 304 exposed at the bottom of cavity 312 is removed by etching.

As an example, cavity 312 has larger lateral dimensions than cavity 310, these dimensions being, for example, measured in a plane parallel to layer 200, that is, in a plane parallel to the upper surface of layer 200, and, thus, to the upper surfaces of layers 300, 302, 304, 306, and 308.

FIG. 7 shows, in a simplified cross-section view, an embodiment of a step of a manufacturing method following the step of FIG. 6.

In FIG. 7, cavity 310 has been filled with at least one conductive material to form a via, or via metallization, 106 of metal level L2. This via 106 is then in contact with the conductive element 200 of metal level L1.

Further, cavity 312 has been filled with at least one conductive material to form a line metallization 104 of metal level L2. This line metallization 104 is then in contact with via 106.

A chemical-mechanical polishing (CMP) is then performed, down to layer 308. Thus, line metallization 104 is flush with the upper surface of layer 308, which corresponds to the upper surface of level L2.

More particularly, in this embodiment, which corresponds to a double damascene process, the two cavities 310 and 312 are simultaneously filled with at least one conductive material, that is, this or these conductive material(s) are simultaneously deposited in the two cavities. Thus, the conductive material(s) filling cavity 310 and the conductive material(s) filling cavity 312 are identical.

As an example, copper is used during the simultaneous filling of cavities 310 and 312.

For example, the filling of cavities 310 and 312 comprises the deposition of a diffusion barrier layer, for example, made of TaNTa, followed by a deposition of a copper seed layer, followed by a deposition, for example, an electrochemical deposition, of copper.

At the end of the steps illustrated in relation with FIGS. 2 to 7, metal level L2 comprises the stack of the successive layers 300, 302, 304, 306, and 308, a line metallization 104 extending through layers 308, 306, and 304, and a conductive via (or via metallization) 106 extending into layer 302 and through layer 300, from line metallization 104 to the conductive element 200 of level L1. In particular, line metallization 104 is flush with the upper surface of layer 308. Further, line metallization 104 is in contact along its entire upper periphery, with layer 308.

An advantage of the method described hereabove in relation with the steps of FIGS. 2 to 7 is that the anneal for improving the quality of the oxide of layers 302 and 306 is carried out immediately after the deposition of layer 306 (that is, before the deposition of layer 308) but before the forming of metallizations 104 and 106. This enables, on the one hand, to decrease the anneal temperature as compared with a final anneal carried out at the end of the manufacturing of an interconnection structure, while maintaining a comparable oxide quality, and, on the other hand, not to damage the conductive material(s), for example, the copper, of metallizations 104 and 106 as a result of the anneal. As only one annealing step is performed for improving the oxide quality of both layers 302 and 306, the number of manufacturing steps is advantageously reduced compared with a manufacturing process where a further heat treatment of the oxide layer 302 would have been performed between the deposition of oxide layer 302 and the deposition of dielectric layer 306.

Although the method has been described hereabove in relation with the forming of metal level L2 on metal level L1, this method may be applied to form any of the metal levels of the interconnection structure other than level L1, or even may be applied to form any of the metal levels of the interconnection structure.

According to an embodiment, the steps described hereabove are implemented to form each metal level of the interconnection structure which rests on an underlying metal level of the interconnection structure. In other words, according to an embodiment, each of the metal levels of the interconnection structure other than level L1 is formed by implementing the above-described steps.

For example, from FIG. 7, metal level L3 may be formed on metal level L2. In this case, the layer 300 of metal level L3 is deposited on top of and in contact with the layer 308 of metal level L2, and the via metallization 106 of metal level L3 thus formed will be in contact with a conductive element 200, that is, a line metallization 104, of the underlying metal level L2.

FIG. 8 shows, in a simplified cross-section view, another embodiment of a step of a manufacturing method following the step of FIG. 2.

In FIG. 8, a dielectric layer 800 has been deposited, for example by a full-plate deposition, on the structure shown in FIG. 2. More particularly, layer 800 has been deposited on top of and in contact with metal level L1, or, in other words, on top of and in contact with the upper surface of metal level L1.

As an example, layer 800 comprises a single dielectric layer, for example made of silicon nitride.

As an alternative example, layer 800 corresponds to a stack of a plurality of dielectric layers, for example made of silicon nitride.

After the deposition of layer 800, an oxide layer 802 was deposited, for example by full-plate deposition, on top of and in contact with layer 800.

Layer 802 is, for example, referred to as an inter-metal dielectric (IMD) layer and separates the line metallizations of the metal level to which it belongs from the line metallizations of the underlying metal level.

As an example, the deposition of layer 802 is performed at a temperature lower than or equal to 300° C.

Layer 802 is made, for example, of silicon oxide, preferably of undoped silicon oxide, also referred to, for example, as undoped silicon glass (USG).

Layer 802 is thicker than layer 800, for example at least ten times as thick as layer 800. As an example, layer 802 comprises a single dielectric layer, for example made of silicon oxide. As an alternative example, layer 802 corresponds to a stack of a plurality of dielectric layers, for example, made of silicon oxide.

Preferably, the material of layer 802 is selectively etchable over the material of layer 800, so that layer 800 is used as an etch stop layer during the etching of cavities in layer 802.

After the deposition of layer 802, an anneal is carried out. More particularly, the anneal is carried out immediately after the deposition of layer 802, that is, for example, before any new deposition or etching step.

As an example, the anneal is carried out in a neutral atmosphere of nitrogen (N2) or hydrogenated nitrogen (N2H2).

As an example, the anneal is carried out at a temperature higher than the temperature of deposition of layer 802, but lower, for example, than 350° C.

As an example, the anneal is carried out at the atmospheric pressure.

As an example, the anneal is carried out without UV (Ultra Violet) treatment.

This anneal enables to improve the quality of the oxide of layer 802, for example by removing traces of moisture in this layer. For example, this annealing step is configured to remove, in layer 802, traces of moisture, hydrogen, and O—H bonds. In particular, the objective of this annealing step is not to remove the carbon bonds. Indeed, the objective of this annealing is not to modify the electrical properties, for example to improve the dielectric permittivity, but rather to eliminate the traces of moisture which could be absorbed by layer 802 after its deposition.

For example, in comparison, the objective of the heat treatments disclosed in US 2011/0049719 A1 is to remove porogen in low k layers when the heat treatments are calcination carried out with UV irradiation at a temperature comprised between 350 and 420° C., or burn the carbon elements in low k layer when the heat treatment is calcination carried out at 300 to 420° C. under inert gas atmosphere without UV irradiation.

These calcinating steps allow for reducing the permittivity below 3.0, and to improve the reliability, for example regarding TDDB (Time Dependent Dielectric Breakdown) tests. Thus, these calcinating steps modify the electrical properties of the low k layers.

After the anneal, a dielectric layer 814 is deposited, for example by a deposition over the entire wafer, on top of and in contact with layer 802. The deposition of the layer is carried out immediately after the anneal, that is, for example, before any further deposition or etching step.

As an example, layer 814 enables to protect the oxide of layer 802 after the anneal, to preserve the qualities of the oxide, layer 814 being referred to, for example, as an encapsulation layer.

As an example, layer 814 comprises a single dielectric layer, for example made of silicon nitride or of aluminum oxide.

As an alternative example, layer 814 corresponds to a stack of a plurality of dielectric layers, for example made of silicon nitride and/or of aluminum oxide.

As an example, layer 814 has a thickness of the same order of magnitude as the thickness of layer 800, that is, for example, the ratio of the thicknesses of layers 800 and 814 is smaller than ten, preferably smaller than 5.

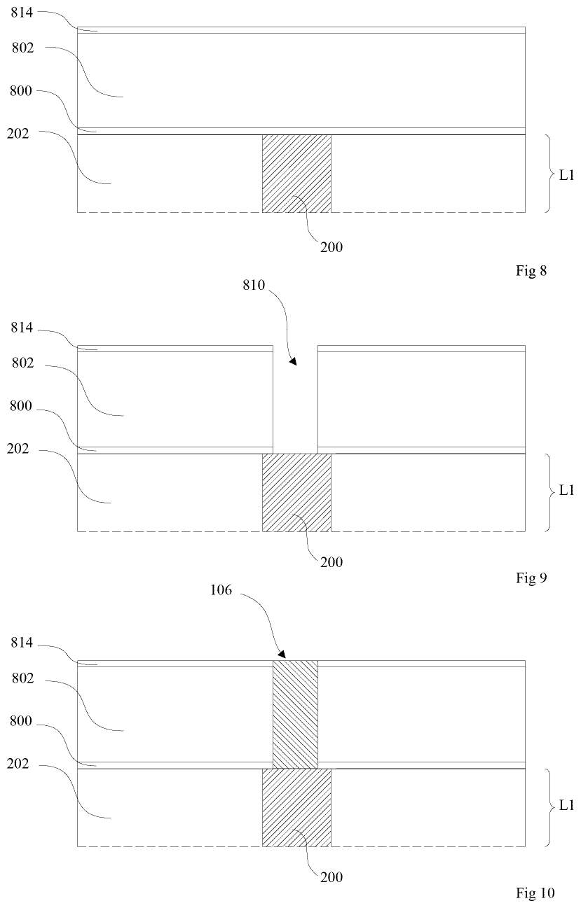

FIG. 9 shows, in a simplified cross-section view, an embodiment of a step of a manufacturing method following the step of FIG. 8.

In FIG. 9, a cavity 810 has been etched down to the conductive element 200 of metal level L1. The etching of cavity 810 is preferably stopped on the upper surface of conductive element 200. Cavity 810 runs through at least layer 800 and layer 802.

More particularly, in this embodiment where cavity 810 is etched after the deposition of layer 814 but before subsequent deposition steps, cavity 810 runs through layers 814, 802, and 800.

As an example, the etching of cavity 810 is stopped on layer 800, which is then used as an etch stop layer, after which the portion of layer 800 exposed at the bottom of cavity 810 is removed by etching, so that cavity 810 extends all the way to element 200.

As an example, element 200 is flush with the bottom of cavity 810.

FIG. 10 shows, in a simplified cross-section view, an embodiment of a step of a manufacturing method following the step of FIG. 9.

In FIG. 10, cavity 810 has been filled with at least one conductive material to form a via, or via metallization, 106 of metal level L2. This via 106 is then in contact with the conductive element 200 of metal level L1.

For example, copper is used during the filling of cavity 810.

For example, the filling of cavity 810 comprises the deposition of a diffusion barrier layer, for example, made of TaNTa, followed by a deposition of a copper seed layer, followed by a deposition, for example, an electrochemical deposition, of copper.

A chemical-mechanical polishing (CMP) is then carried out, down to layer 814. Thus, via metallization 106 is flush with the upper surface of layer 814.

FIG. 11 shows, in a simplified cross-section view, an embodiment of a step of a manufacturing method following the step of FIG. 10.

In FIG. 10, a dielectric layer 804 has been deposited, for example by full-plate deposition, on top of (or above) layer 802. In this embodiment, layer 804 is preferably deposited above layer 802, on top of and in contact with layer 814 and the top of via metallization 106.

As an example, layer 804 comprises a single dielectric layer, for example made of silicon nitride.

As an alternative example, layer 804 corresponds to a stack of a plurality of dielectric layers, for example made of silicon nitride.

As an example, layer 804 has a thickness of the same order of magnitude as the thickness of layer 800, that is, for example, the ratio of the thicknesses of layers 800 and 804 is smaller than ten, preferably smaller than 5.

An oxide layer 806 was then deposited, for example by full-plate deposition over the entire wafer, on top of and in contact with layer 804.

Layer 806 is, for example, referred to as an inter-level dielectric (ILD) layer, and corresponds to an insulating layer in which the line metallizations of the metal level to which it belongs are formed.

As an example, the deposition of layer 806 is performed at a temperature lower than or equal to 300° C.

Layer 806 is, for example, made of silicon oxide, preferably of undoped silicon oxide, also referred to, for example, as undoped silicon glass (USG).

Layer 806 is thicker than layer 804, for example at least ten times as thick as layer 804. As an example, layer 806 comprises a single dielectric layer, for example made of silicon oxide. As an alternative example, layer 806 corresponds to a stack of a plurality of dielectric layers, for example made of silicon oxide.

Preferably, the material of layer 806 is selectively etchable over the material of layer 804, so that layer 804 is used as an etch stop layer during the etching of cavities in layer 806.

After the deposition of layer 806, an anneal is carried out. More particularly, the anneal is carried out immediately after the deposition of layer 806, that is, for example, before any further deposition or etching step.

As an example, the anneal is carried out in a neutral atmosphere of nitrogen (N2) or hydrogenated nitrogen (N2H2).

As an example, the anneal is carried out at a temperature higher than the temperature of deposition of layers 302 and 306, but lower, for example, than 350° C.

As an example, the anneal is carried out at the atmospheric pressure.

As an example, the anneal is carried out without UV (Ultra Violet) treatment.

This anneal enables to improve the quality of the oxide of layer 806, for example by removing traces of moisture in this layer.

For example, this annealing step is configured to remove, in layer 806, traces of moisture, hydrogen, and O—H bonds. In particular, the objective of this annealing step is not to remove the carbon bonds. Indeed, the objective of this annealing is not to modify the electrical properties, for example to improve the dielectric permittivity, but rather to eliminate the traces of moisture which could be absorbed by layer 806 after its deposition.

For example, in comparison, the objective of the heat treatments disclosed in US 2011/0049719 A1 is to remove porogen in low k layers when the heat treatments are calcination carried out with UV irradiation at a temperature comprised between 350 and 420° C., or burn the carbon elements in low k layer when the heat treatment is calcination carried out at 300 to 420° C. under inert gas atmosphere without UV irradiation.

These calcinating steps allow for reducing the permittivity below 3.0, and to improve the reliability, for example regarding TDDB (Time Dependent Dielectric Breakdown) tests. Thus, these calcinating steps modify the electrical properties of the low k layers.

After the anneal, a dielectric layer 808 is deposited, for example by a deposition over the entire wafer, on top of and in contact with layer 806. The deposition of the layer is carried out immediately after the anneal, that is, for example, before any further deposition or etching step.

As an example, layer 808 enables to protect the oxide of layer 806 after the anneal, to preserve the qualities of the oxide, layer 808 being referred to, for example, as an encapsulation layer.

As an example, layer 808 comprises a single dielectric layer, for example made of silicon nitride or of aluminum oxide.

As an alternative example, layer 808 corresponds to a stack of a plurality of dielectric layers, for example made of silicon nitride and/or of aluminum oxide.

As an example, layer 808 has a thickness of the same order of magnitude as the thicknesses of layers 800, 804, and 814, that is, for example, the ratio of the thicknesses of layers 800 (or 804 or 814) and 808 is smaller than ten, preferably smaller than 5.

A cavity 812 was then etched through layers 808, 806, and 804. Cavity 812 is etched so that cavity 810 emerges onto the bottom of cavity 812. More particularly, in this embodiment where cavity 810 is already filled by via 106, the etching of cavity 812 is stopped on the top of via 106 and of layer 814, whereby the cavity 810 filled by via 106 emerges onto the bottom of cavity 812.

As an example, the etching of cavity 812 is stopped on layer 804, which is then used as an etch stop layer, after which the portion of layer 804 exposed at the bottom of cavity 812 is removed by etching to expose the top of via 106 and layer 814.

As an example, cavity 812 has lateral dimensions greater than those of cavity 810, these dimensions being, for example, measured in a plane parallel to layer 200, that is, in a plane parallel to the upper surface of layer 200, and, thus, to the upper surfaces of layers 800, 802, 804, 806, 808, and 814.

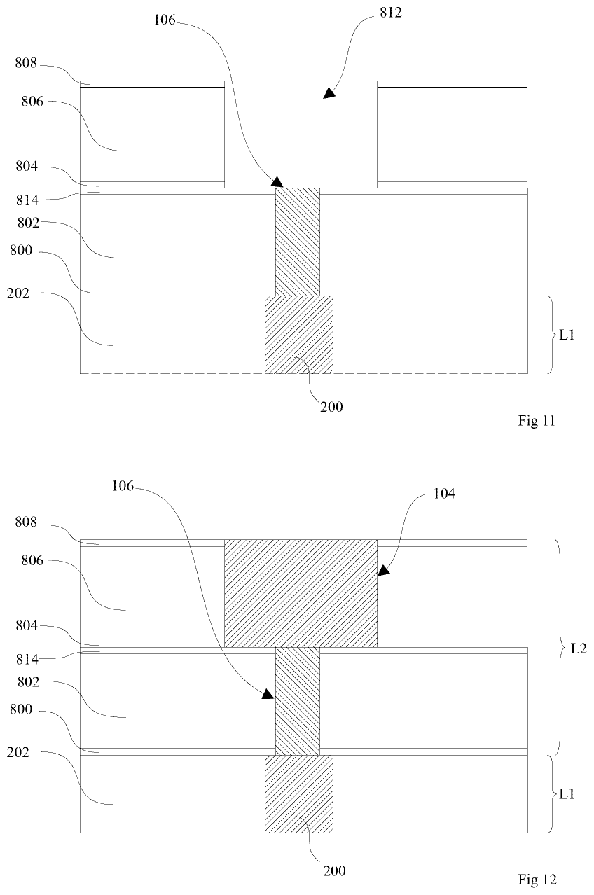

FIG. 12 shows, in a simplified cross-section view, an embodiment of a step of a manufacturing method following the step of FIG. 11.

In FIG. 12, cavity 812 has been filled with at least one conductive material to form a line metallization 104 of metal level L2. This line metallization 104 is then in contact with via 106.

As an example, copper is used during the filling of cavity 812.

For example, the filling of cavity 812 comprises the deposition of a diffusion barrier layer, for example made of TaNTa, followed by a deposition of a copper seed layer, followed by a deposition, for example, an electrochemical deposition, of copper.

A chemical-mechanical polishing (CMP) is then carried out, down to layer 808. Thus, line metallization 104 is flush with the upper surface of layer 808.

As compared with the method of double damascene type described in relation with FIGS. 2 to 7, the method described in relation with FIGS. 2 and 8 to 12 is of single damascene type.

At the end of the steps illustrated in relation with FIGS. 2 and 8 to 12, metal level L2 comprises the stack of successive layers 800, 802, 814, 804, 806, and 808, a line metallization 104 extending through layers 808, 806, and 804, and a conductive via (or via metallization) 106 extending through layers 814, 802, and 800, from line metallization 104 to the conductive element 200 of level L1. In particular, line metallization 104 is flush with the upper surface of layer 808. Further, line metallization 104 is in contact, along its entire upper periphery, with layer 808. Similarly, via metallization 106 is flush with the upper surface of layer 814. Further, via metallization 106 is in contact, along its entire upper periphery, with layer 814.

An advantage of the method described hereabove in relation with the steps of FIGS. 2 and 8 to 12 is that the anneal to improve the quality of the oxide of layer 806 is implemented immediately after the deposition of layer 806 (thus before the deposition of layer 808) but before the forming of metallizations 104, and, further, that the anneal for improving the quality of the oxide of layer 802 is implemented immediately after the deposition of layer 802 (thus before the deposition of layer 814) but before the forming of metallizations 104 and 106. This enables, on the one hand, to decrease the temperature of the anneals as compared with a final anneal carried out at the end of the manufacturing of an interconnection structure, while maintaining a comparable oxide quality, and, on the other hand, to avoid damaging the conductive material(s), for example copper, of metallizations 104 and 106 as a result of the anneals. In particular, during the anneal carried out immediately after the deposition of layer 806, although via metallization 106 has already formed, it is not degraded by the anneal, since it is protected by layer 804 and, for example, by layer 806.

Although the method of FIGS. 2 and 8 to 12 has been described hereabove in relation to the forming of metal level L2 on metal level L1, this method can be applied to form any of the metal levels of the interconnection structure other than level L1, or even can be applied to form any of the metal levels of the interconnection structure.

According to an embodiment, the steps described hereabove in relation with FIGS. 2 and 8 to 12 are implemented to form each metal level of the interconnection structure which rests on an underlying metal level of the interconnection structure. In other words, according to an embodiment, each of the metal levels of the interconnection structure other than level L1 is formed by carrying out the above-described steps.

For example, from FIG. 12, metal level L3 may be formed on metal level L2. In this case, the layer 800 of metal level L3 is deposited on top of and in contact with the layer 808 of metal level L2, and the via metallization 106 of the metal level L3 thus formed will be in contact with a conductive element 200, that is, a line metallization 104, of the underlying metal level L2.

Various embodiments and variants have been described. Those skilled in the art will understand that certain features of these various embodiments and variants may be combined, and other variants will occur to those skilled in the art. In particular, the materials indicated hereabove as an example may be modified by those skilled in the art while keeping the described advantages. For example, layer 302 (or 802) may be made of SiOC or SiOCH rather than of silicon oxide. As another example, layer 306 (or 806) may be made of SiOC or of SiOCH rather than of silicon oxide.

Finally, the practical implementation of the described embodiments and variants is within the abilities of those skilled in the art based on the functional indications given hereabove.

A manufacturing method is summarized as including the following steps: depositing a first dielectric layer (300; 800) on top of and in contact with a first metal level (L1) of an interconnection structure (100); depositing a first oxide layer (302; 802) on top of and in contact with the first dielectric layer (300; 800); depositing a second dielectric layer (304; 804) on the first oxide layer; depositing a second oxide layer (306; 806) on top of and in contact with the second dielectric layer (304; 804), performing a first anneal and depositing a third dielectric layer (308; 808) on top of and in contact with the second oxide layer (306: 806); etching a first cavity (310; 810) down to a conductive element of the first metal level, the first cavity running through at least the first oxide layer (302; 802) and the first dielectric layer (300; 800); etching a second cavity (312; 812) through the third dielectric layer (308; 808), the second oxide layer (306; 806), and the second dielectric layer (304; 804), so that the first cavity (310; 810) emerges onto the bottom of the second cavity (312; 812); filling the first cavity (310; 810) with at least one conductive material to form therein a conductive via (106) of a second metal level (L2) of the interconnection structure (100); filling the second cavity (312; 812) with at least one conductive material to form therein a line metallization (104) of the second metal level (L2) of the interconnection structure (100); and performing a first chemical-mechanical polishing down to the third dielectric layer (308; 808), after the filling of the second cavity (312; 812).

The first and second oxide layers (302, 306; 802, 806) are made of silicon oxide, preferably of undoped silicon oxide.

The first oxide layer (302; 802) is made of a material selectively etchable over the material of the first dielectric layer (300; 800).

The first dielectric layer (300; 800) is made of silicon nitride.

The second oxide layer (306; 806) is made of a material selectively etchable over the material of the second dielectric layer (304; 804).

The second dielectric layer (304; 804) is made of aluminum oxide or of silicon nitride.

The third dielectric layer (308; 808) is made of aluminum oxide or of silicon nitride.

The second dielectric layer (304) is deposited on top of and in contact with the first oxide layer (302); the etching of the first cavity (310) is carried out after the deposition of the third dielectric layer (308); the first cavity (310) is further etched through the third dielectric layer (308), the second oxide layer (306), and the second dielectric layer (304); and the first and second cavities (310, 312) are simultaneously filled, said at least one conductive material filling the first cavity (310) and said at least one conductive material filling the second cavity (312) being identical.

The deposition of the first oxide layer (802) is followed by a second anneal and the second anneal is followed by the deposition of a fourth dielectric layer (814) on top of and in contact with the first oxide layer (802).

The etching and the filling of the first cavity (810) are carried out after the deposition of the fourth dielectric layer (814) and before the deposition of the second dielectric layer (804), the first cavity (310) being etched through the fourth dielectric layer (814), the first oxide layer (802), and the first dielectric layer (800); a second chemical-mechanical polishing down to the fourth dielectric layer (814) is carried out after the filling of the first cavity (812) and before the deposition of the second dielectric layer (804); and the second dielectric layer (804) is deposited on top of and in contact with the fourth dielectric layer (814) and a top of the conductive via (106) of the second metal level (L2) of the interconnection structure (100).

The etching of the second cavity (812) is stopped on the top of the conductive via (106) and the fourth dielectric layer (814), the first cavity (810) filled by said conductive via (106) emerging onto the bottom of the second cavity (812).

The fourth dielectric layer (814) is made of aluminum oxide or of silicon nitride.

A device is summarized as including an interconnection structure (100), the interconnection structure including a first metal level (L1) and a second metal level (L2) resting on the first metal level (L1), the second metal level (L2) including: a first dielectric layer (300; 800) resting on top of and in contact with the first metal level (L1); a first oxide layer (302; 802) resting on top of and in contact with the first dielectric layer (300; 800); a second dielectric layer (304; 804) arranged on the first oxide layer (302; 802); a second oxide layer (306; 806) resting on top of and in contact with the second dielectric layer (304; 804); a third dielectric layer (308; 808) resting on top of and in contact with the second oxide layer (306; 806); a line metallization (104) extending through the third dielectric layer (308; 808), the second oxide layer (306; 806), and the second dielectric layer (304; 804), the line metallization being flush with an upper surface of the third dielectric layer (308; 808); and a conductive via (106) extending into the first oxide layer (302; 802) and through the first dielectric layer (300; 800), from the line metallization (104) to a conductive element (200) of the first metal level (L1).

In the second metal level (L2), the line metallization (104) is bordered by the third dielectric layer (308; 808) along its entire upper periphery.

The second dielectric layer (304) lies on top of and in contact with the first oxide layer (302), the line metallization (104) being able to partially extend into the first oxide layer (302); or a fourth dielectric layer (814) lies on top of and in contact with the first oxide layer (802), the second dielectric layer (804) lies on top of and in contact with the fourth dielectric layer (814), the conductive via (106) being flush with an upper surface of the fourth dielectric layer (814) and being bordered by the fourth dielectric layer (814) along its entire upper periphery.

The various embodiments described above can be combined to provide further embodiments. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A manufacturing method comprising the following steps:
forming a first dielectric layer on a first metal level of an interconnection structure;
forming a first oxide layer on the first dielectric layer;
forming a second dielectric layer on the first oxide layer;
forming a second oxide layer on the second dielectric layer;
performing a first anneal;
forming a third dielectric layer on the second oxide layer;
etching a first cavity along a first direction to a conductive element of the first metal level, the first cavity extending through at least the first oxide layer and the first dielectric layer;
etching a second cavity along the first direction through the second oxide layer and the second dielectric layer, the first cavity including a first opening in the second cavity;
forming a conductive via of a second metal level of the interconnection structure by filling the first cavity with at least one conductive material, the conductive via being in direct contact with the first oxide layer;
forming a line metallization of the second metal level of the interconnection structure by filling the second cavity with at least one conductive material, the line metallization being in direct contact with the second oxide layer; and
performing a first chemical-mechanical polishing down to the third dielectric layer, after the filling of the second cavity.

2. The method according to claim 1, wherein the first and second oxide layers includes silicon oxide.

3. The method according to claim 1, wherein the first oxide layer includes a material selectively etchable over a dielectric material of the first dielectric layer.

4. The method according to claim 1, wherein the first dielectric layer includes silicon nitride.

5. The method according to claim 1, wherein the second oxide layer includes a material selectively etchable over a dielectric material of the second dielectric layer.

6. The method according to claim 1, wherein the second dielectric layer includes aluminum oxide.

7. The method according to claim 1, wherein the third dielectric layer includes silicon nitride.

8. The method according to claim 1, wherein:
the second dielectric layer is formed on the first oxide layer, wherein the second dielectric layer is deposited without a prior heat treatment of the first oxide layer;
the etching of the first cavity is carried out after the forming the third dielectric layer;
the first cavity is further etched through the third dielectric layer, the second oxide layer, and the second dielectric layer; and
the first and second cavities are simultaneously filled.

9. The method according to claim 1, wherein the forming the first oxide layer is followed by a second anneal and the second anneal is followed by forming a fourth dielectric layer on the first oxide layer.

10. The method according to claim 9, wherein:
the etching and the filling of the first cavity are carried out after the forming the fourth dielectric layer and before the forming the second dielectric layer, the first cavity being etched through the fourth dielectric layer, the first oxide layer, and the first dielectric layer;
a second chemical-mechanical polishing down to the fourth dielectric layer is carried out after the filling of the first cavity and before the forming the second dielectric layer; and
the second dielectric layer is formed on the fourth dielectric layer and a first surface of the conductive via of the second metal level of the interconnection structure.

11. The method according to claim 10, wherein the etching of the second cavity is terminated on the first surface of the conductive via and a first surface of the fourth dielectric layer.

12. The method according to claim 10, wherein the fourth dielectric layer includes aluminum oxide.

13. A device, comprising:
an interconnection structure, the interconnection structure including a first metal level and a second metal level on the first metal level, the second metal level including:
a first dielectric layer on with the first metal level;
a first oxide layer on the first dielectric layer;
a second dielectric layer on the first oxide layer;
a second oxide layer on the second dielectric layer;
a third dielectric layer on the second oxide layer;
a line metallization extending through the third dielectric layer, the second oxide layer, and the second dielectric layer, a first surface of the line metallization being coplanar with a first surface of the third dielectric layer; and
a conductive via extending into the first oxide layer and through the first dielectric layer, from the line metallization to a conductive element of the first metal level, the conductive via and line metallization being a single continuous metal component.

14. The device according to claim 13, wherein, the second metal level is entirely covered by the third dielectric layer.

15. The device according to claim 13, wherein:
the second dielectric layer lies on the first oxide layer, the line metallization partially extending into the second dielectric layer; and
a fourth dielectric layer lies between the first oxide layer and the second dielectric layer, the fourth dielectric layer having a first surface directly in contact with the second dielectric layer, the conductive via being coplanar with the first surface of the fourth dielectric layer.

16. A device, comprising:
a first metal level, including:
an insulating layer with a first surface opposite a second surface along a first direction; and
a conductive element in the insulating layer and coplanar with the first surface of the insulating layer;
a second metal level on the first metal level, the second metal level including:
a first dielectric layer on the first surface of the insulating layer;
a first oxide layer on the first dielectric layer;
a second oxide layer on the first oxide layer;
a second dielectric layer on the second oxide layer, the second dielectric layer having a first surface opposite the second oxide layer; and
a conductive component extending along the first direction from the first surface of the second dielectric layer to the conductive element, the conductive component being one continuous metal component including:
a first portion extending along the first direction through the second dielectric layer and second oxide layer; and
a second portion extending along the first direction through the first oxide layer and first dielectric layer.

17. The device according to claim 16, wherein the first portion has a first dimension in a second direction transverse to the first direction and the second portion has a second dimension in the second direction, the second dimension being smaller than the first dimension.

18. The device according to claim 17, wherein the first portion is coplanar with the first surface of the second dielectric layer.

19. The device according to claim 18, comprising a third dielectric layer between the first and second oxide layers, the first portion extending entirely through the second dielectric layer, the second oxide layer, and the third dielectric layer.

20. The device according to claim 17, wherein the conductive element has a third dimension in the second direction larger than the second dimension and smaller than the first dimension.
